(19) United States
(12) Patent Application Publication
(10) Pub. No.: US 2025/0120047 A1
(43) Pub. Date: Apr. 10, 2025

(54) TEMPERATURE ADJUSTMENT DEVICE, SINGLE-PHASE LIQUID COOLING SYSTEM AND CONTROL METHOD FOR SINGLE-PHASE LIQUID COOLING SYSTEM

(71) Applicant: Suzhou MetaBrain Intelligent Technology Co., Ltd., Suzhou, Jiangsu (CN)

(72) Inventors: Huanlai ZHU, Suzhou, Jiangsu (CN); An WU, Suzhou, Jiangsu (CN); Guangzhi LIU, Suzhou, Jiangsu (CN)

(21) Appl. No.: 18/985,438

(22) Filed: Dec. 18, 2024

Related U.S. Application Data
(63) Continuation of application No. PCT/CN2023/134435, filed on Nov. 27, 2023.

(30) Foreign Application Priority Data
Feb. 14, 2023 (CN) 202310109064.4

(51) Int. Cl. H05K 7/20

(52) U.S. Cl. CPC H05K 7/20281; H05K 7/20254; H05K 7/20263; H05K 7/20272

(57) ABSTRACT

The present application relates to a temperature adjustment device, a single-phase liquid cooling system and a control method for a single-phase liquid cooling system. The temperature adjustment device includes a first casing, a second casing, a first valve body, a second valve body, and a phase transition material. The first casing is provided with a first chamber therein, and the first casing is provided with a liquid inlet, a first liquid outlet, and a second liquid outlet which are in communication with the first chamber. The second casing is provided with a second chamber therein, and the second casing is arranged within the first chamber. The first valve body has a first plugging position for isolating the first liquid outlet from the liquid inlet, and a first opening position for allowing communication between the first liquid inlet and the first liquid outlet.

### CROSS-REFERENCE TO RELATED APPLICATIONS

This application is a continuation of International Patent Application No. PCT/CN2023/134435, filed on Nov. 27, 2023, which claims priority to Chinese Patent Application No. 202310109064.4 filed with the China National Intellectual Property Administration on Feb. 14, 2023 and entitled “INTELLIGENT TEMPERATURE ADJUSTMENT DEVICE, SINGLE-PHASE LIQUID COOLING SYSTEM AND CONTROL METHOD FOR SINGLE-PHASE LIQUID COOLING SYSTEM”. International Patent Application No. PCT/CN2023/134435 and Chinese Patent Application No. 202310109064.4 are which is incorporated herein by reference in their entireties.

### FIELD

The present application relates to the technical field of liquid cooling heat dissipation, and in particular, to a temperature adjustment device, a single-phase liquid cooling system and a control method for a single-phase liquid cooling system.

### BACKGROUND

At present, booming development of cloud computing, big data, and the like and explosive growth of data volume have all promoted rapid development of a data center market. However, construction of a data center is often plagued by environmental issues such as excessive energy consumption. Constructing a green data center is an inevitable trend in development of the data center. To meet a requirement of continuously growing computing power, power density of a single cabinet is higher and higher. A cabinet with a power density of 40 KW will become mainstream. When the power density of the single cabinet reaches 20 kW, an existing air cooling system is close to an economically effective cooling limit thereof. Against this background, a liquid cooling data center heat dissipation technology with a low Power Usage Effectiveness (PUE) of all energy consumed by the data center to the energy consumed by an Information Technology (IT) load and high cooling density has emerged. Cold plate liquid cooling uses a liquid working medium with a high specific heat capacity to quickly take away heat, and has higher cooling efficiency and a lower PUE value.

In an existing cold plate single-phase liquid cooling system, temperature of a heat source (for example, a Central Processing Unit (CPU)) often needs to be accurately controlled. Factors that affect the temperature of the heat source include a coolant temperature of the secondary side, a coolant flow rate of the secondary side, and heat dissipation power consumption of the heat source. Since the heat dissipation power consumption of the heat source is a variable, the heat dissipation power consumption changes in different time periods, and meanwhile, the coolant temperature of the secondary side and the coolant flow rate of the secondary side will also affect each other, the temperature of the heat source cannot be accurately controlled by adjusting one of the items.

In an existing water-water heat exchange liquid cooling system and a liquid supply temperature and a flow rate control method for a liquid cooling source of the water-water heat exchange liquid cooling system, in the disclosed control method, opening of a control valve on a primary side is subjected to closed-loop control by setting a temperature target value, taking the secondary side coolant temperature as a temperature feedback value, and a difference between the temperature target value and the temperature feedback value as a temperature control quantity, so as to indirectly control the secondary side coolant temperature, thereby controlling the temperature of the heat source. However, in the control method, additional temperature measuring points need to be added. A Programmable Logic Controller (PLC) system performs Proportion Integral Differential (PID) adjustment according to measuring point data. Due to a high specific heat capacity of the coolant, temperature adjustment requires a long time and has significant lag. Taking a polling time of 2 seconds as an example, the final stabilization time of the secondary side coolant temperature is over 100 seconds through indirect PID adjustment. When the power consumption of the heat source changes frequently (for example, the power consumption of the CPU changes at 30 seconds), a phenomenon of one thing after another will occur, that is, a temperature of a coolant delivered to the heat source deviates from the target value due to an impact of a change of the heat dissipation power consumption when the temperature has not yet reached stability in the last time, and finally, causes that an actual operating temperature of the CPU deviates from a set value for a long time, which results in temperature control failure.

In this regard, in a prior art, a temperature adjustment device is often added in the liquid cooling system to adjust the temperature of the coolant. However, the existing temperature adjustment device cannot adjust the temperature without the cooperation of external measuring points, and lag in temperature adjustment cannot be avoided.

### SUMMARY

Therefore, a technical solution to be solved by the present application is to overcome a defect that lag in temperature adjustment cannot be avoided since a temperature adjustment device relies on external measurement points during adjusting a temperature of a coolant in a prior art.

To overcome the foregoing problem, the present application provides a temperature adjustment device, including a first casing, a second casing, a first valve body, a second valve body, and a phase transition material. The first casing is provided with a first chamber therein, and the first casing is provided with a liquid inlet, a first liquid outlet, and a second liquid outlet which are in communication with the first chamber respectively. The second casing is provided with a second chamber therein, and the second casing is arranged within the first chamber. A second end of the second casing is fixedly connected to an inner wall of the first casing, and a first end of the second casing extends to the second liquid outlet. The first valve body is movably arranged within the first chamber, and the first valve body is movable between a first plugging position and a first opening position. In the first plugging position, the first valve body isolates the first liquid outlet from the liquid inlet, and in the first opening position, the first liquid outlet is in communication with the liquid inlet. The second valve body is in flexible connection with a first end of the second casing and is in transmission connection with the first valve body, and the second valve body has a second plugging position for plugging the second liquid outlet and a second opening position for opening the second liquid outlet. The phase transition material is filled in the second chamber and is suitable for changing phases according to an inlet liquid temperature, so as to drive the second valve body and the first valve body to move.

In the temperature adjustment device according to the present application, the phase transition material may be a mixture of paraffin, metal particles, oxide powder, and the like.

In the temperature adjustment device according to the present application, an annular flange protrudes from a chamber wall of the first chamber. The annular flange partitions the first chamber into a first chamber body and a second chamber body that are in communication with each other. The first liquid outlet is in communication with the first chamber body. Both the liquid inlet and the second liquid outlet are in communication with the second chamber body. The first valve body is movably arranged within the second chamber body. when that the first valve body is at the first plugging position, the first valve body is plugged at the annular flange, and when the first valve body is at the first opening position, the first valve body is away from the annular flange.

In the temperature adjustment device according to the present application, a second end of the second casing is fixedly connected to an inner wall of the first chamber body, and the second end of the second casing penetrates through an inner ring of the annular flange to extend towards the second liquid outlet; and the first valve body is sleeved over a periphery of the second casing, and is in sliding fit with the second casing.

In the temperature adjustment device according to the present application, the second liquid outlet is provided on a bottom chamber wall of the second chamber body opposed to the annular flange; and the liquid inlet is provided on a side chamber wall of the second chamber body adjacent to the bottom chamber wall and feeds liquid towards a periphery of the second casing.

The temperature adjustment device according to the present application further includes:
a transmission part, where one of the first valve body or the second valve body is fixedly connected to a first end of the transmission part, and the other one is in flexible connection with a second end of the transmission part; and
a return elastic part, where two ends of the return elastic part are fixedly connected to the first valve body and the second valve body respectively.

In the temperature adjustment device according to the present application, the return elastic part is a return spring, and the return elastic part is sleeved over the periphery of the transmission part.

In the temperature adjustment device according to the present application, the transmission part is tubular and is sleeved over a periphery of the second casing.

The temperature adjustment device according to the present application further includes a stop structure, arranged within the second chamber. The phase transition material is filled between the stop structure and the second valve body. The stop structure is suitable for stopping the phase transition material from moving towards a direction of the first liquid outlet.

In the temperature adjustment device according to the present application, the stop structure includes:
a baffle, connected to an interior of the second chamber to partition the second chamber into a phase transition chamber and a stop chamber, and the phase transition chamber is filled with the phase transition material; and
a stop lever, arranged within the stop chamber, where a first end of the stop lever contacts an inner wall of the first casing that is fixedly connected to a second end of the second casing, and the second end of the stop lever contacts the baffle.

In the temperature adjustment device according to the present application, the baffle is made of an elastic material, a shape of the baffle matches an inner chamber of the second chamber, and a periphery of the baffle is fixedly connected to the inner chamber of the second chamber.

In the temperature adjustment device according to the present application, the baffle is a rubber plate.

In the temperature adjustment device according to the present application, the second end of the stop lever close to the baffle is provided with a head, an end of the head faces the second valve body, and the baffle is suitable for undergoing elastic deformation under an action of the head.

In the temperature adjustment device according to the present application, a thickness of the baffle gradually increases from a periphery of the baffle to a position corresponding to the end of the head.

In the temperature adjustment device according to the present application, the baffle is located in the second chamber body.

The present application further provides a single-phase liquid cooling system, including a primary side circulation pipeline, a secondary side circulation pipeline, and a heat exchanger. The primary side circulation pipeline inputs a coolant to the heat exchanger. The secondary side circulation pipeline includes:
the foregoing temperature adjustment device;
a second circulating pump, where a liquid inlet end of the second circulating pump is in communication with a hot flow outlet of a cooling structure of a heat source, a liquid outlet end of the second circulating pump is in communication with the liquid inlet, the first liquid inlet is in communication with a cold flow inlet of the cooling structure through the heat exchanger, and the second liquid inlet is in communication with the cold flow inlet; and
an adjustment valve, arranged close to the cold flow inlet, located between the cold flow inlet and the second liquid inlet, and located between the cold flow inlet and the heat exchanger.

In the single-phase liquid cooling system according to the present application, a plurality of cooling structures are arranged in parallel; and the cold flow inlet of each cooling structure of the plurality of cooling structures matches one of the adjustment valves.

In the single-phase liquid cooling system according to the present application, the adjustment valve is an electromagnetic adjustment valve.

In the single-phase liquid cooling system according to the present application, the primary side circulation pipeline includes a first circulating pump; a water inlet end of the first circulating pump is in communication with a heat dissipation outlet of a heat dissipation device; and a water outlet end is in communication with a heat dissipation inlet of the heat dissipation device through the heat exchanger.

The present application further provides a control method for the foregoing single-phase liquid cooling system, variables that affect a temperature of the heat source include heat dissipation power consumption of the heat source, and a temperature of a coolant and a flow rate of the coolant delivered to the cooling structure of the heat source by the secondary side circulation pipeline.

The control method includes the following steps:
decoupling the temperature of the coolant from the flow rate of the coolant and the heat dissipation power consumption of the heat source; and
performing coupled control on the flow rate of the coolant and the heat dissipation power consumption of the heat source.

In the control method according to the present application, the step of decoupling the temperature of the coolant from the flow rate of the coolant and the heat dissipation power consumption of the heat source includes: controlling the temperature of the coolant at a constant temperature through the temperature adjustment device.

Further, the step of performing coupled control on the flow rate of the coolant and the heat dissipation power consumption of the heat source includes: adjusting a valve opening of the adjustment valve according to a relational expression between the heat dissipation power consumption of the heat source and the valve opening of the adjustment valve corresponding to the heat source; and the valve opening of the adjustment valve is in direct proportion to the flow rate of the coolant.

Further, the relational expression is as follows:

B=(Q/K)²/Qmax,

where B is the valve opening of the adjustment valve;

Q is the heat dissipation power consumption of the heat source;

K is a coefficient; and

Qmax is the flow rate of the coolant in a case that the adjustment valve is completely open.

### BRIEF DESCRIPTION OF THE DRAWINGS

To describe the technical solutions in the specific implementation manners of the present application or in the prior art more clearly, the following briefly describes the accompanying drawings required for describing the specific implementation manners or the prior art. Apparently, the accompanying drawings in the following description show merely some implementation manners of the present application, and a person of ordinary skill in the art may still derive other drawings from these accompanying drawings without creative efforts.

FIG. 1 is a schematic diagram of a first temperature adjustment condition of a temperature adjustment device according to the present application;

FIG. 2 is a schematic diagram of a second temperature adjustment condition of a temperature adjustment device according to the present application;

FIG. 3 is a schematic diagram of a third temperature adjustment condition of a temperature adjustment device according to the present application;

FIG. 4 is a schematic diagram of a single-phase liquid cooling system according to the present application; and

FIG. 5 is a flowchart of a control method according to the present application.

### REFERENCE SIGNS IN THE DRAWINGS

1, first casing; 11, first chamber; 111, first chamber body; 112, second chamber body; 12, liquid inlet; 13, first liquid outlet; 14, second liquid outlet; 15, annular flange; 151, inner ring; 2, second casing; 21, second chamber; 22, first end; 23, second end; 3, first valve body; 4, second valve body; 5, phase transition material; 6, transmission part; 7, return elastic part; 8, stop structure; 83, baffle; 82, stop lever; 81, head; 100, primary side circulation pipeline; 101, first circulating pump; 102, heat dissipation device; 200, secondary side circulation pipeline; 201, temperature adjustment device; 202, second circulating pump; 203, heat source; 204, cooling structure; 205, adjustment valve; 300, heat exchanger; 400, control module, and 500, data acquisition module.

### DETAILED DESCRIPTION

Technical solutions of the present application are clearly and completely described below with reference to accompanying drawings. Apparently, described embodiments are part rather than all of the embodiments of the present application. All other embodiments obtained by those of ordinary skill in the art based on the embodiments of the present application fall within the scope of protection of the present application. In descriptions of the present application, it is to be noted that orientations or positional relationships indicated by terms “center”, “upper”, “lower”, “left”, “right”, “vertical”, “horizontal”, “inner”, “outer”, and the like are the orientations or positional relationships shown based on the accompanying drawings, and are merely for the convenience of describing the present application and simplifying the descriptions, rather than indicating or implying that the devices or elements referred to need to have particular orientations, and constructed and operated in particular orientations. Therefore, it cannot be construed as a limitation to the present application. In addition, terms “first”, “second”, and “third” are merely used for description, and cannot be understood as indicating or implying relative importance.

In the descriptions of the present application, it is to be noted that, unless otherwise specified and limited, terms “mount”, “interconnect”, and “connect” are to be broadly understood. For example, the terms may refer to fixed connection and may also refer to detachable connection or integration; the terms may refer to mechanical connection and may alternatively refer to electrical connection; the terms may refer to direct mutual connection, may alternatively refer to indirect connection through a medium, and may refer to communication in two components. Those of ordinary skill in the art may understand specific meanings of the above terms in the present application according to specific situations.

In addition, technical features involved in different embodiments of the present application described below can be combined with one another as long as there is no conflict among them.

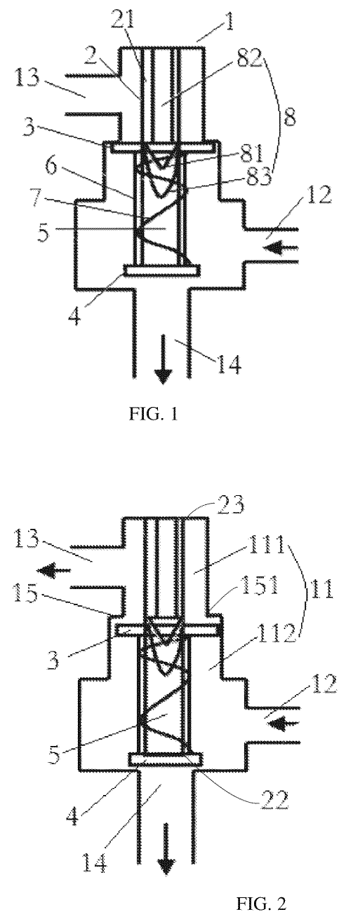

As shown in FIG. 1 to FIG. 3, some embodiments disclose a temperature adjustment device 201, including a first casing 1, a second casing 2, a first valve body 3, a second valve body 4, and a phase transition material 5. The first casing 1 is provided with a first chamber 11 therein, and the first casing 1 is provided with a liquid inlet 12, a first liquid outlet 13 and a second liquid outlet 14 which are in communication with the first chamber 11 respectively. The second casing 2 is provided with a second chamber 21 therein, and the second casing 2 is arranged within the first chamber 11. The first valve body 3 is movably arranged within the first chamber 11. The first valve body is movable between a first plugging position, where the first valve body isolates the first liquid outlet from the liquid inlet, and a first opening position, where the first liquid outlet is in communication with the liquid inlet. The second valve body 4 is in flexible connection with a first end 22 of the second casing 2 and is in transmission connection with the first valve body 3, and the second valve body 4 has a second plugging position for plugging the second liquid outlet 14 and a second opening position for opening the second liquid outlet 14. The phase transition material 5 is filled in the second chamber 21 and is suitable for changing phases to the inlet liquid temperature, so as to drive the second valve body 4 and the first valve body 3 to move.

The first liquid outlet 13 is suitable for being in communication with a cooling structure 204 (for example, a single-phase cold plate) of a heat source 203 through a heat exchanger 300. The second liquid outlet 14 is suitable for being in direct communication with the cooling structure 204 of the heat source 203. The temperature adjustment device 201 according to the present application can control a phase transition state of the phase transition material 5 according to a temperature of a coolant at the liquid inlet 12, so as to drive the first valve body 3 and the second valve body 4 to move to change opening/closing states of the first liquid outlet 13 and the second liquid outlet 14, then a coolant at a high coolant temperature may be discharged through the first liquid outlet 13 separately and enter the heat exchanger 300 to perform heat exchange to reduce to a corresponding temperature after cooling, or a coolant at a corresponding temperature may be directly discharged through the second liquid outlet 14 separately, or a coolant that is discharged through the first liquid outlet 13 and is cooled by the heat exchanger 300 is mixed with a coolant discharged from the second liquid outlet 14 to obtain a coolant at a corresponding temperature, so as to control the temperature of the coolant delivered to the cooling structure 204 of the heat source 203. The temperature adjustment device 201 according to the present application controls the temperature of the coolant delivered to the cooling structure 204 of the heat source 203 by using inherent properties of an object, for example, material change properties between the phase transition material 5 and temperature. The temperature of the coolant is controlled reliably and safely in real time without PID adjustment, without relying on external temperature measuring points, and without being limited by accuracy deviation or failure of the external temperature measuring points.

A coolant contacts the second casing 2 first after entering the liquid inlet 12, so the phase transition material 5 filled in the second chamber 21 of the second casing 2 deforms more sensitively. A second end 23 of the second casing 2 is fixedly connected to an inner wall of the first casing 1, and the first end 22 of the second casing 2 extends towards the second liquid outlet 14. The second end 23 of the second casing 2 is fixed, when deformation occurs, the first end 22 of the second casing 2 may move due to a phase transition of the phase transition material 5, so that the second valve body 4 in flexible connection with the first end 22 may open or plug the second liquid outlet 14 during moving.

Further, the second valve body 4 is in flexible connection with the first end 22 of the second casing 2. The flexible connection includes that the second valve body 4 is connected to the second casing 2 through an elastic tube, for example, a rubber hose, or a corrugated tube. When the phase transition material 5 changes from a solid state to a liquid state, the second valve body 4 and the second casing 2 that are in the flexible connection are elastically stretched under extrusion of the phase transition material 5, and the second valve body 4 moves in a direction where the second liquid outlet 14 is located. When the phase transition material 5 changes a liquid state to a solid state, the second valve body 4 and the second casing 2 that are in the flexible connection return to original positions under actions of an elastic force and a negative pressure. The second valve body 4 is hermetically connected to the second casing 2 to enclose a hermetic second chamber 21. In some embodiments, the second valve body 4 may be of a plate-like structure. The heat source 203 may be, for example, an electrical component such as a CPU or other electrical devices in a server. The cooling structure 204 may be a cooling structure 204 that performs cooling and heat dissipation through a coolant, such as a single-phase cold plate.

In the temperature adjustment device according to some embodiments, the phase transition material 5 may be a mixture of paraffin, metal particles, oxide powder, and the like.

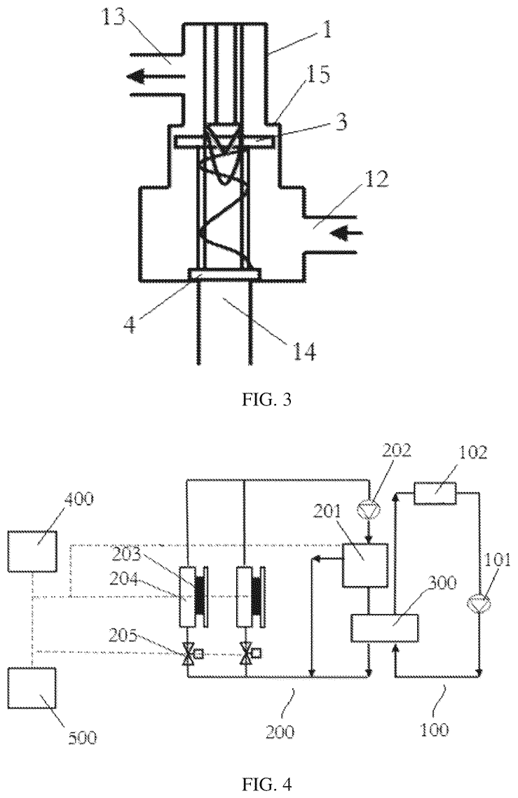

A specific temperature adjustment process of the temperature adjustment device 201 includes that, when a temperature of a coolant at the liquid inlet 12 is relatively high, the phase transition material 5 gradually changes from a solid state to a liquid state, and the volume occupied in the second chamber 21 gradually increases, so as to push the second valve body 4 to move towards the second plugging position to gradually plug the second liquid outlet 14. The first valve body 3 is in transmission connection with the second valve body 4, and the first valve body 3 moves towards the first opening position to gradually open the first liquid outlet 13. In this process, both the first liquid outlet 13 and the second liquid outlet 14 are in open states. As shown in FIG. 2, the coolant flows out from the first liquid outlet 13 is cooled by the heat exchanger 300 and then is mixed with the coolant flows out from the second liquid outlet 14, and a mixture enters the cooling structure 204 of the heat source 203 to absorb heat, thereby cooling the heat source 203. When the temperature of the coolant of the liquid inlet 12 is up to a certain value, the first liquid outlet 13 is completely open and the second liquid outlet 14 is closed, as shown in FIG. 3, and all coolant enters the cooling structure 204 of the heat source 203 to absorb heat after being cooled by the heat exchanger 300. When a temperature of a coolant at the liquid inlet 12 is relatively low, the phase transition material 5 gradually changes from a liquid state to a solid state, and the volume occupied in the second chamber 21 gradually decreases, so that the second valve body 4 gradually returns the second opening position and gradually opens the second liquid outlet 14 to drive the first valve body 3 to move towards the first plugging position to gradually isolate the first liquid outlet 13 from the liquid inlet 12. In this process, both the first liquid outlet 13 and the second liquid outlet 14 are in open states. As shown in FIG. 2, the coolant flows out from the first liquid outlet 13 is cooled by the heat exchanger 300 and then is mixed with the coolant flows out from the second liquid outlet 14, and a mixture enters the cooling structure 204 of the heat source 203 to absorb heat, thereby cooling the heat source 203. When the temperature of the coolant of the liquid inlet 12 drops to a certain value, the first liquid outlet 13 is closed, the second liquid outlet 14 is completely open, as shown in FIG. 1, and the coolant directly enters the cooling structure 204 of the heat source 203 to absorb heat through the second liquid outlet 14.

In some embodiment, an annular flange 15 is protruded on a chamber wall of the first chamber 11. The annular flange 15 partitions the first chamber 11 into a first chamber body 111 and a second chamber body 112 that are in communication with each other. The first liquid outlet 13 is in communication with the first chamber body 111. Both the liquid inlet 12 and the second liquid outlet 14 are in communication with the second chamber body 112. The first valve body 3 is movably arranged within the second chamber body 112, and has the first plugging position that is plugged at the annular flange 15 and the first opening position that is away from the annular flange 15.

The first valve body 3 plugs at the annular flange 15 to close the first chamber body 111, so as to plug the first liquid outlet 13. Both the first valve body 3 and the second valve body 4 are arranged within the second chamber body 112 to short a distance therebetween, so that the first valve body 3 is more easily in transmission connection with the second valve body 4, and then the first valve body 3 is controlled more sensitively.

In a specific implementation, the first casing 1 is of a rotary structure. The first chamber body 111 and the second chamber body 112 are distributed in an axial direction, and a diameter of the first chamber body 111 is less than that of the second chamber body 112. An interior of the second chamber body 112 further includes a transition section and a liquid inlet section that are distributed in a stepped manner. The transition section is located between the first chamber body 111 and the liquid inlet section. The liquid inlet 12 is provided on a periphery of the liquid inlet section. The second liquid outlet 14 is provided on one side of the liquid inlet section away from the transition section. A diameter of the transition section is greater than that of the first chamber body 111, and is less than that of the liquid inlet section. The coolant may remain a long time after entering the liquid inlet section, and performs heat exchange with the phase transition material 5 for a long time, so control is more accurate. In an optional implementation, a liquid inlet direction of the liquid inlet 12 is consistent with a tangent direction of the liquid inlet section. The coolant may remain a longer time in the liquid inlet section after entering the liquid inlet 12.

In some embodiment, a second end 23 of the second casing 2 is fixedly connected to an inner wall of the first chamber body 111, and a first end 22 of the second casing penetrates through inner ring 151 of the annular flange 15 to extend towards the second liquid outlet 14. The first valve body 3 is sleeved over a periphery of the second casing 2, and is in sliding fit with the second casing 2. The second casing 2 may limit an action of the first valve body 3 to prevent the first valve body 3 from deviating during moving, which results in that the annular flange 15 cannot be effectively plugged.

In some embodiment, the second liquid outlet 14 is provided on a bottom chamber wall of the second chamber body 112 opposed to the annular flange 15. The liquid inlet 12 is provided on a side chamber wall of the second chamber body 112 adjacent to the bottom chamber wall and feeds liquid towards the periphery of the second casing 2. It is ensured that the coolant which enters from the liquid inlet 12 may be in direct contact with the second casing 2, and heat may be better transferred to the phase transition material 5 inside the second casing 2, so that the phase transition material 5 may change phases more timely according to the temperature of the coolant.

The temperature adjustment device 201 according to the present application further includes a transmission part 6 and a return elastic part 7. One of the first valve body 3 and the second valve body 4 is fixedly connected to a first end of the transmission part 6, and the other one is in flexible connection with a second end of the transmission part 6. Two ends of the return elastic part 7 are fixedly connected to the first valve body 3 and the second valve body 4 respectively. An arrangement of the transmission part 6 achieves a transmission connection between the first valve body 3 and the second valve body 4, so that the first valve body 3 and the second valve body 4 can achieve real-time linkage, and plugging and opening of the first liquid outlet 13 and the second liquid outlet 14 can be adjusted in real time according to a phase transition state of the phase transition material 5. The return elastic part 7 is suitable for driving the first valve body 3 to return to an original position when the second valve body 4 is not subjected to a force, and ensures a plugging effect of the first valve body 3 on the first liquid outlet 13.

As a replaceable implementation, alternatively, the transmission part 6 may be arranged to achieve stable transmission between the first valve body 3 and the second valve body 4. Alternatively, the return elastic part 7 may be arranged, and elastic transmission between the first valve body 3 and the second valve body 4 is achieved through the return elastic part 7.

In some embodiment, the return elastic part 7 is a return spring, and is sleeved over the periphery of the transmission part 6. The transmission part 6 limits the return spring to prevent the return spring from inclining or bending during moving or stressing, affecting a direction of force applied to the first valve body 3 and/or the second valve body 4 by the return spring.

In some embodiment, the transmission part 6 is tubular and is sleeved over the periphery of the second casing 2. A structure is simple, a connection is more stable, a transmission effect is better, and errors such as inclining of the second valve body 4 cannot occur.

As a replaceable implementation, alternatively, the transmission part 6 may include at least three transmission levers, which are uniformly distributed on a periphery of the first valve body 3 in a circumferential direction of the first valve body 3. The return elastic part 7 may alternatively include at least three return springs. Each return spring is sleeved over a periphery of each transmission lever.

The temperature adjustment device 201 according to some embodiments further include a stop structure 8, arranged within the second chamber 21. The phase transition material 5 is filled between the stop structure 8 and the second valve body 4. The stop structure 8 is suitable for stopping the phase transition material 5 from moving towards a direction of the first liquid outlet 13. The stop structure 8 stops the phase transition material 5 at a position close to the liquid inlet 12 and the second liquid outlet 14, so that the phase transition material 5 is in contact with a coolant earlier and changes phase more sensitively, and a problem that the second valve body 4 cannot return to open the second liquid outlet 14 because the phase transition material 5 continues changing phases when close to the first liquid outlet 13 could be avoided.

In some embodiment, the stop structure 8 includes a baffle 83 and a stop lever 82. The baffle 83 is connected to an interior of the second chamber 21 to partition the second chamber 21 into a phase transition chamber and a stop chamber. The phase transition material 5 is filled in the phase transition chamber. The stop lever 82 is arranged within the stop chamber. A first end of the stop lever 82 contacts an inner wall of the first casing 1 that is fixedly connected to the second end 83 of the second casing 2, and the second end of the stop lever 82 contacts the baffle 83. The stop lever 82 prevents the baffle 83 from moving towards the direction of the first liquid outlet 13, thereby ensuring a driving force of the phase transition material 5 on the second valve body 4.

In some embodiment, the baffle 83 is made of an elastic material, a shape of the baffle 83 matches an inner chamber of the second chamber 21, and a periphery is fixedly connected to the inner chamber of the second chamber 21. When the phase transition material 5 changes from a solid state to a liquid state, the baffle 83 may contract under a pressure to apply a force to the stop lever 82. Since the stop lever 82 contacts the inner wall of the first casing 1 that is fixedly connected to the second end 83 of the second casing 2, the stop lever 82 cannot move, but the stop lever applies a reversing acting force to the baffle 83 to push the phase transition material 5 to move reversely. The baffle 83 is made of an elastic material, which can undergo elastic deformation when the baffle 83 is subjected to a force to avoid damage of the baffle 83 due to frequent stress.

In a specific implementation, a periphery of the baffle 83 is welded or bonded with a chamber wall of the inner chamber of the second chamber 21. Alternatively, the periphery of the baffle 83 is in interference fit with the inner chamber of the second chamber 21.

As a replaceable implementation, alternatively, the periphery of the baffle 83 is provided with a hard connecting ring, the chamber wall of the inner chamber of the second chamber 21 is provided with an annular groove, and the hard connecting ring is connected to an interior of the annular groove.

In some embodiment, the baffle 83 is a rubber plate. The material is low in cost and is easy to mold.

In some embodiment, a first end of the stop lever 82 close to the baffle 83 is provided with a head 81, an end of the head 81 faces the second valve body 4, and the baffle 83 is suitable for undergoing elastic deformation under an action of the head 81. The head 81 may promote deformation of the baffle 83 with a lower center and higher periphery when the baffle 83 is subjected to a force. A central position is closer to the second valve body 4, which increases contact area between the baffle 83 and the phase transition material 5, and reduces the pressure applied to the baffle 83 by the phase transition material 5.

The head 81 is round hammer shaped, and the end of the head 81 is in smooth transition to avoid puncturing the baffle 83. A diameter of one end of the head 81 away from the end is greater than that of the stop lever 82.

In some embodiment, a thickness of the baffle 83 gradually increases from a periphery to a position corresponding to the end of the head 81. The thickness of the position where the baffle 83 matches the end of the head 81 is increased, so as to prevent the end from puncturing the baffle 83.

In some embodiment, the baffle 83 is located in the second chamber body 112. The phase transition chamber partitioned by the baffle 83 is limited in the second chamber body 112, so as to ensure that the phase transition material 5 can change phases at the first time when the coolant enters the liquid inlet 12, and avoid an impact on a phase transition of the phase transition material 5 to affect normal opening of the second valve body 4 if the phase transition material 5 is located in the first chamber body 111.

As shown in FIG. 4, some embodiments further disclose a single-phase liquid cooling system, including a primary side circulation pipeline 100, a secondary side circulation pipeline 200, and a heat exchanger 300. The primary side circulation pipeline 100 inputs a coolant to the heat exchanger 300 to cool the coolant at a relatively high temperature input to the heat exchanger 300 by the secondary side circulation pipeline 200.

The secondary side circulation pipeline 200 includes the foregoing temperature adjustment device 201, a second circulating pump 202, and an adjustment valve 205.

The temperature adjustment device 201 includes a first casing 1, a second casing 2, a first valve body 3, a second valve body 4, and a phase transition material 5. The first casing 1 is provided with a first chamber 11 therein, and the first casing 1 is provided with a liquid inlet 12, a first liquid outlet 13, and a second liquid outlet 14 which are in communication with the first chamber 11. The second casing 2 is provided with a second chamber 21 therein, and the second casing 2 is arranged within the first chamber 11. A second end 23 of the second casing 2 is fixedly connected to an inner wall of the first casing 1, and a first end 22 of the second casing 2 extends to the second liquid outlet 14. The first valve body 3 is movably arranged within the first chamber 11 and has a first plugging position for isolating the first liquid outlet from the liquid inlet, and a first opening position for allowing communication between the first liquid inlet and the first liquid outlet. The second valve body 4 is in flexible connection with the first end 22 of the second casing 2 and is in transmission connection with the first valve body 3, and the second valve body 4 has a second plugging position for plugging the second liquid outlet 14 and a second opening position for opening the second liquid outlet 14. The phase transition material 5 is filled in the second chamber 21 and is suitable for changing phases according to an inlet liquid temperature, so as to drive the second valve body 4 and the first valve body 3 to move.

According to the temperature adjustment device 201 according to the present application, the first liquid outlet 13 is suitable for being in communication with a cooling structure 204 of a heat source 203 through a heat exchanger 300. The second liquid outlet 14 is suitable for being in direct communication with the cooling structure 204 of the heat source 203. The temperature adjustment device 201 according to the present application can control a phase transition state of the phase transition material 5 according to a temperature of a coolant at the liquid inlet 12, so as to drive the second valve body 4 and the first valve body 3 to move to change opening/closing states of the first liquid outlet 13 and the second liquid outlet 14, then a coolant at a high coolant temperature may be discharged through the first liquid outlet 13 separately and enter the heat exchanger 300 to perform heat exchange to reduce to a corresponding temperature after cooling, or a coolant at a corresponding temperature may be directly discharged through the second liquid outlet 14 separately, or a coolant that is discharged through the first liquid outlet 13 and is cooled by the heat exchanger 300 is mixed with a coolant discharged from the second liquid outlet 14 to obtain a coolant at a corresponding temperature, so as to control the temperature and the flow rate of the coolant delivered to the cooling structure 204 of the heat source 203.

A liquid inlet end of the second circulating pump 202 is in communication with a hot flow outlet of the cooling structure 204 of the heat source 203, a liquid outlet end is in communication with the liquid inlet 12 of the temperature adjustment device 201. The second circulating pump 202 may provide flowing circulation power for the coolant discharged from the hot flow outlet of the cooling structure 204 of the heat source 203, provide power for flow of the coolant in the secondary side circulation pipeline, and is a power source for achieving cooling circulation. The first liquid outlet 13 of the temperature adjustment device 201 is in communication with a cold flow inlet of the cooling structure 204 through the heat exchanger 300, and the second liquid outlet 14 is in communication with the cold flow inlet.

The adjustment valve 205 is arranged close to the cold flow inlet of the cooling structure 204 of the heat source 203, is located between the cold flow inlet of the cooling structure 204 of the heat source 203 and the second liquid outlet 14, and is located between the cold flow inlet and the heat exchanger 300. The adjustment valve 205 is a flow adjustment valve, which can adjust a flow rate entering the cold flow inlet and achieve real-time and accurate control on a flow rate and a temperature of a coolant in cooperation with the temperature adjustment device 201.

In some embodiment, the single-phase liquid cooling system further includes a control module 400 and a data acquisition module 500. The control module 400 is in communication connection with each of the data acquisition module 500, the cooling structure 204, and the temperature adjustment device 201. The data acquisition module 500 is in communication connection with the adjustment valve 205, and is configured to acquire opening information of the adjustment valve 205 and send the opening information to the control module 400. The control module 400 controls the temperature adjustment device 201 to enable the coolant at a constant temperature according to actual heat dissipation requirements, and adjusts the opening of the adjustment valve 205 according to heat dissipation power consumption of the heat source 203 fed back by the cooling structure 204 and the opening information of the adjustment valve 205, thereby adjusting the flow rate of the adjustment valve 205.

The communication connection refers to communication performed between connected devices through transmission interaction of signals, including a wired connection (for example, connections through a conducting wire or a network cable) and a wireless connection (for example, WiFi, 4G connections).

In the single-phase liquid cooling system according to the present application, real-time, reliable, and accurate control on the temperature of the coolant of the secondary side circulation pipeline 200 is achieved by the secondary side circulation pipeline 200 through the temperature adjustment device 201, and then opening of the adjustment valve 205 is correspondingly adjusted according to the heat dissipation power consumption of the heat source 203, so as to achieve real-time, reliable, and accurate control on a temperature of the heat source 203. The lag of the conventional liquid cooling system when the temperature of the coolant is indirectly controlled by adjusting opening of a control valve of a primary side circulation pipeline is solved, and the problem about reliability of the conventional liquid cooling system caused by frequent changes of the power consumption of the heat source 203 and relying on temperature measuring points on a secondary side is avoided.

In some embodiment, a plurality of cooling structures 204 are arranged in parallel; and the cold flow inlet of each cooling structure 204 matches one of the adjustment valves 205. Each cooling structure 204 matches at least one heat source 203. The single-phase liquid cooling system according to some embodiments can perform real-time, reliable, and accurate cooling and heat dissipation on a plurality of heat sources 203 simultaneously, and achieve real-time, reliable, and accurate control on temperature of the plurality of heat sources 203.

In some embodiment, the adjustment valve 205 is an electromagnetic adjustment valve. It has high adjustment accuracy, can adjust accurately and effectively, and can control automatically without adjusting manually.

In some embodiment, the primary side circulation pipeline 100 includes a first circulating pump 101. A water inlet end of the first circulating pump 101 is in communication with a heat dissipation outlet of a heat dissipation device 102. A water outlet end is in communication with a heat dissipation inlet of the heat dissipation device 102 through the heat exchanger 300. The heat dissipation device 102 cools the coolant at a relatively high temperature flowing out from the heat exchanger 300. Under an action of the first circulating pump 101, the cooled coolant at a relatively low temperature continues entering the heat exchanger 300 to absorb heat to cool the coolant in the secondary side circulation pipeline 200. In some embodiments, the heat dissipation device is an air-liquid heat exchanger.

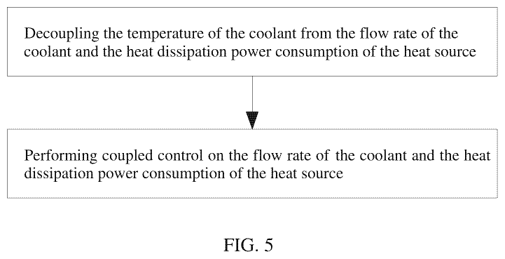

Variables that affect the temperature of the heat source 203 include heat dissipation power consumption of the heat source 203, and a temperature of a coolant and a flow rate of the coolant delivered to the cooling structure 204 of the heat source 203 by the secondary side circulation pipeline 200. As shown in FIG. 5, some embodiments further disclose a control method for the foregoing single-phase liquid cooling system, including the following steps: the temperature of the coolant is decoupled from the flow rate of the coolant and the heat dissipation power consumption of the heat source 203; and coupled control is performed on the flow rate of the coolant and the heat dissipation power consumption of the heat source 203.

An impact of the temperature of the coolant on the heat dissipation power consumption and the flow rate of the coolant is eliminated first, and then real-time, reliable, and accurate control on the temperature of the heat source 203 is achieved according to the coupled control of the flow rate of the coolant and the heat dissipation power consumption of the heat source 203.

In some embodiment, the step that the temperature of the coolant is decoupled from the flow rate of the coolant and the heat dissipation power consumption of the heat source 203 includes: the temperature of the coolant is controlled at a constant temperature through the temperature adjustment device 201.

In some embodiment, the step that coupled control is performed on the flow rate of the coolant and the heat dissipation power consumption of the heat source 203 includes: valve opening of the adjustment valve 205 is adjusted according to a relational expression between the heat dissipation power consumption of the heat source 203 and the valve opening of the adjustment valve 205 corresponding to the heat source 203. The valve opening of the adjustment valve 205 is in direct proportion to the flow rate of the coolant.

In some embodiment, the relational expression is as follows: B=(Q/K)²/Qmax,

where B is the valve opening of the adjustment valve 205; Q is the heat dissipation power consumption of the heat source 203; K is a coefficient; and Qmax is a flow rate of the coolant in a case that the valve is completely open.

In a case that the coolant is at a certain temperature, certain heat dissipation power consumption requires certain flow rate of the coolant at the same set temperature.

A formula for calculating a convective heat-transfer coefficient hₓ in heat transfer is as follows:

$${h}_{x} = 0.332 ( λ / x ) {Re}^{0.5} P {r}^{1 / 3} ,$$

where λ is a heat conductivity coefficient, x is a feature size, and Pr is a Prandtl number, which are all constants under design conditions.

A formula for a Reynolds number is as follows:

$$Re = ρ vx / η ,$$

where Vis a flow velocity of the coolant in the cooling structure 204, p is a density of the coolant, x is a feature size, n is a dynamic viscosity, and p, x, and n are all constants under design conditions.

It can be learned from the above two formulas that, in a case that other parameters are constant, hₓ (the convective heat-transfer coefficient) is in direct proportion to the 0.5 power of the flow velocity inside the cold plate, that is, is in direct proportion to the 0.5 power of the flow rate Qᵥ.

A formula for calculating convective heat transfer is as follows:

$$Q = {h}_{x} A ( {t}_{w} - {t}_{∞} ) ,$$

where t_{w} is a temperature of the heat source 203, t_{∞} is a temperature of a coolant entering the cooling structure 204 (a temperature constantly output by the temperature adjustment device), and A is heat exchange area. In a case that the same temperature of the heat source 203 is maintained, t_{w}, t_{∞}, and A are all constants under the design conditions.

Therefore, it can be learned that Q and hₓ are in a linear relationship, that is,

Q=KQᵥ^{0.5}

where, Q is the heat dissipation power consumption, Qᵥ is a flow rate of the coolant, and K is a coefficient, that is, Qᵥ=(Q/K)².

A corresponding relationship between opening of an adjustment type three-eccentric center butterfly valve and a flow rate is shown in the following Table 1 and Table 2:

TABLE 1

| Relative stroke % | | 0 | 10 | 20 | 30 | 40 | 50 |
|---|---|---|---|---|---|---|---|
| Relative | Ideal | 3.33 | 31.78 | 44.82 | 54.84 | 63.30 | 70.75 |
| flow | quick | | | | | | |
| rate | opening % | | | | | | |

TABLE 2

| Relative stroke % | | 60 | 70 | 80 | 90 | 100 |
|---|---|---|---|---|---|---|
| Relative | Ideal | 77.49 | 83.69 | 89.46 | 94.87 | 100 |
| flow | quick | | | | | |
| rate | opening % | | | | | |

Qᵥ=QₘₐₓB, Qₘₐₓ is the flow rate of the coolant in a case that the valve is completely open, and B is valve opening.

Therefore, it can be obtained that B=(Q/K)²/Qₘₐₓ.

In conclusion, a one-to-one correspondence between a relative stroke, that is, the opening, of the adjustment valve 205 can be obtained according to the heat dissipation power consumption Q of the heat source 203.

The coolant of the secondary side circulation pipeline 200 is output at a constant temperature through real-time control of the temperature adjustment device, so the heat dissipation power consumption of the heat source 203 of a corresponding branch needs to be read and the valve opening of the corresponding adjustment valve 205 need to be output in a temperature control and adjustment process of the system. Taking a polling time of 2 seconds as an example, the valve opening can be simultaneously output after the power consumption of the heat source 203 of the branch is obtained from polling, an opening time of an electromagnetic adjustment valve is 1 second, a stable time for the system to adjust the temperature and the flow rate of the primary side circulation pipeline 100 and the secondary side circulation pipeline 200 according to the changes of the power consumption is 3 seconds in total. Compared with 100 seconds in an existing conventional solution, the time can be reduced by two orders of magnitude. For a system with frequently changing power consumption, the control method can follow quickly, and a phenomena of temperature control failure that an actual operating temperature of a CPU deviates a set value for a long time in the conventional solution is avoided.

Apparently, the foregoing embodiments are merely examples for describing clearly rather than limiting implementations. For those of ordinary skill in the art, other different forms of variations or changes may alternatively be made on the basis of the foregoing description. It is not necessary and impossible to exhaustively list all implementations here. Obvious changes or variations arising therefrom are still within the scope of protection created by the present application.

What is claimed is:

1. A temperature adjustment device, comprising:
a first casing, provided with a first chamber therein, wherein the first casing is provided with a liquid inlet, a first liquid outlet and a second liquid outlet respectively in communication with the first chamber;
a second casing, provided with a second chamber therein, wherein the second casing is arranged within the first chamber;
a first valve body, movably arranged within the first chamber, wherein the first valve body is movable between a first plugging position and a first opening position, wherein in the first plugging position, the first valve body isolates the first liquid outlet from the liquid inlet, and in the first opening position, the first liquid outlet is in communication with the liquid inlet;
a second valve body, in flexible connection with a first end of the second casing and in transmission connection with the first valve body, wherein the second valve body has a second plugging position for plugging the second liquid outlet and a second opening position for opening the second liquid outlet; and
a phase transition material, being filled in the second chamber and suitable for changing phases according to an inlet liquid temperature to drive the second valve body and the first valve body to move.

2. The temperature adjustment device according to claim 1, wherein an annular flange protrudes from a chamber wall of the first chamber; the annular flange partitions the first chamber into a first chamber body and a second chamber body in communication with each other; the first liquid outlet is in communication with the first chamber body; both the liquid inlet and the second liquid outlet are in communication with the second chamber body; the first valve body is movably arranged within the second chamber body, when the first valve body is at the first plugging position, the first valve body is plugged at the annular flange, and when the first valve body is at the first opening position, the first valve body is away from the annular flange.

3. The temperature adjustment device according to claim 2, wherein a second end of the second casing is fixedly connected to an inner wall of the first chamber body, and the first end of the second casing penetrates through an inner ring of the annular flange to extend towards the second liquid outlet; and the first valve body is sleeved over a periphery of the second casing, and is in sliding fit with the second casing.

4. The temperature adjustment device according to claim 2, wherein the second liquid outlet is provided on a bottom chamber wall of the second chamber body opposed to the annular flange; and the liquid inlet is provided on a side chamber wall of the second chamber body adjacent to the bottom chamber wall and feeds liquid towards a periphery of the second casing.

5. The temperature adjustment device according claim 1, comprising:
a transmission part, where one of the first valve body or the second valve body is fixedly connected to a first end of the transmission part, and the other one is in flexible connection with a second end of the transmission part; and
a return elastic part, where two ends of the return elastic part are fixedly connected to the first valve body and the second valve body respectively.

6. The temperature adjustment device according to claim 5, wherein the return elastic part is a return spring, and the return elastic part is sleeved over a periphery of the transmission part.

7. The temperature adjustment device according to claim 5, wherein the transmission part is tubular and is sleeved over a periphery of the second casing.

8. The temperature adjustment device according to claim 2, comprising a stop structure, arranged within the second chamber, wherein the phase transition material is filled between the stop structure and the second valve body; and the stop structure is suitable for stopping the phase transition material from moving towards a direction of the first liquid outlet.

9. The temperature adjustment device according to claim 8, wherein the stop structure comprises:
a baffle, connected to an interior of the second chamber to partition the second chamber into a phase transition chamber and a stop chamber, wherein the phase transition chamber is filled with the phase transition material; and
a stop lever, arranged within the stop chamber, wherein a first end of the stop lever contacts an inner wall of the first casing that is fixedly connected to a second end of the second casing, and a second end of the stop lever contacts the baffle.

10. The temperature adjustment device according to claim 9, wherein the baffle is made of an elastic material, a shape of the baffle matches an inner chamber of the second chamber, and a periphery of the baffle is fixedly connected to the inner chamber of the second chamber.

11. The temperature adjustment device according to claim 10, wherein the baffle is a rubber plate.

12. The temperature adjustment device according to claim 10, wherein the second end of the stop lever is provided with a head, an end of the head faces the second valve body, and the baffle is suitable for undergoing elastic deformation under an action of the head.

13. The temperature adjustment device according to claim 12, wherein a thickness of the baffle gradually increases from the periphery of the baffle to a position corresponding to the end of the head.

14. A single-phase liquid cooling system, comprising a primary side circulation pipeline, a secondary side circulation pipeline, and a heat exchanger, wherein the primary side circulation pipeline inputs a coolant to the heat exchanger; the secondary side circulation pipeline comprises:
a temperature adjustment device comprising;
a first casing, provided with a first chamber therein, wherein the first casing is provided with a liquid inlet, a first liquid outlet and a second liquid outlet respectively in communication with the first chamber;
a second casing, provided with a second chamber therein, wherein the second casing is arranged within the first chamber;
a first valve body, movably arranged within the first chamber, wherein the first valve body is movable between a first plugging position and a first opening position, wherein in the first plugging position, the first valve body isolates the first liquid outlet from the liquid inlet, and in the first opening position, the first liquid outlet is in communication with the liquid inlet;
a second valve body, in flexible connection with a first end of the second casing and in transmission connection with the first valve body, wherein the second valve body has a second plugging position for plugging the second liquid outlet and a second opening position for opening the second liquid outlet; and
a phase transition material, being filled in the second chamber and suitable for changing phases according to an inlet liquid temperature to drive the second valve body and the first valve body to move;
a second circulating pump, wherein a liquid inlet end of the second circulating pump is in communication with a hot flow outlet of a cooling structure of a heat source, a liquid outlet end of the second circulating pump is in communication with the liquid inlet, the first liquid outlet is in communication with a cold flow inlet of the cooling structure through the heat exchanger, and the second liquid outlet is in communication with the cold flow inlet; and
an adjustment valve, arranged in proximity to the cold flow inlet, located between the cold flow inlet and the second liquid outlet, and located between the cold flow inlet and the heat exchanger.

15. The single-phase liquid cooling system according to claim 14, wherein a plurality of cooling structures are arranged in parallel; and the cold flow inlet of each cooling structure of the plurality of cooling structures matches one of the adjustment valves.

16. The single-phase liquid cooling system according to claim 15, wherein the primary side circulation pipeline comprises a first circulating pump; a water inlet end of the first circulating pump is in communication a heat dissipation outlet of a heat dissipation device; and a water outlet end of the first circulating pump is in communication a heat dissipation inlet of the heat dissipation device through the heat exchanger.

17. A control method for a single-phase liquid cooling system, wherein, the single-phase liquid cooling system, comprises a primary side circulation pipeline, a secondary side circulation pipeline, and a heat exchanger, wherein the primary side circulation pipeline inputs a coolant to the heat exchanger; the secondary side circulation pipeline comprises:
a temperature adjustment device comprising;
a first casing, provided with a first chamber therein, wherein the first casing is provided with a liquid inlet, a first liquid outlet and a second liquid outlet respectively in communication with the first chamber;
a second casing, provided with a second chamber therein, wherein the second casing is arranged within the first chamber;
a first valve body, movably arranged within the first chamber, wherein the first valve body is movable between a first plugging position and a first opening position, wherein in the first plugging position, the first valve body isolates the first liquid outlet from the liquid inlet, and in the first opening position, the first liquid outlet is in communication with the liquid inlet;
a second valve body, in flexible connection with a first end of the second casing and in transmission connection with the first valve body, wherein the second valve body has a second plugging position for plugging the second liquid outlet and a second opening position for opening the second liquid outlet; and
a phase transition material, being filled in the second chamber and suitable for changing phases according to an inlet liquid temperature to drive the second valve body and the first valve body to move;
a second circulating pump, wherein a liquid inlet end of the second circulating pump is in communication with a hot flow outlet of a cooling structure of a heat source, a liquid outlet end of the second circulating pump is in communication with the liquid inlet, the first liquid outlet is in communication with a cold flow inlet of the cooling structure through the heat exchanger, and the second liquid outlet is in communication with the cold flow inlet; and
an adjustment valve, arranged in proximity to the cold flow inlet, located between the cold flow inlet and the second liquid outlet, and located between the cold flow inlet and the heat exchanger;
the single-phase liquid cooling system variables that affect a temperature of the heat source comprise heat dissipation power consumption of the heat source, and a temperature of the coolant and a flow rate of the coolant delivered to the cooling structure of the heat source by the secondary side circulation pipeline; and
the control method comprises the following steps:
decoupling the temperature of the coolant from the flow rate of the coolant and the heat dissipation power consumption of the heat source; and
performing coupled control on the flow rate of the coolant and the heat dissipation power consumption of the heat source.

18. The control method for the single-phase liquid cooling system according to claim 17, wherein the step of decoupling the temperature of the coolant from the flow rate of the coolant and the heat dissipation power consumption of the heat source comprises: controlling the temperature of the coolant at a constant temperature through the temperature adjustment device.

19. The control method for the single-phase liquid cooling system according to claim 17, wherein the step of performing coupled control on the flow rate of the coolant and the heat dissipation power consumption of the heat source comprises: adjusting a valve opening of the adjustment valve according to a relational expression between the heat dissipation power consumption of the heat source and the valve opening of the adjustment valve corresponding to the heat source; and the valve opening of the adjustment valve is in direct proportion to the flow rate of the coolant.

20. The control method for the single-phase liquid cooling system according to claim 19, wherein the relational expression is as follows:
$$B = {( Q / K )}^{2} / Q max ,$$
wherein B is the valve opening of the adjustment valve;
Q is the heat dissipation power consumption of the heat source;
K is a coefficient; and
Qmax is the flow rate of the coolant when the adjustment valve is completely open.
